(19) United States
(12) Patent Application Publication
(10) Pub. No.: US 2025/0349523 A1
(43) Pub. Date: Nov. 13, 2025

(54) SUBSTRATE PROCESSING APPARATUS AND SUBSTRATE PROCESSING METHOD

(71) Applicant: Tokyo Electron Limited, Tokyo (JP)

(72) Inventors: Takashi ARAMAKI, Miyagi (JP); Lifu LI, Miyagi (JP); Hiroshi TSUJIMOTO, Miyagi (JP)

(73) Assignee: Tokyo Electron Limited, Tokyo (JP)

(21) Appl. No.: 19/278,842

(22) Filed: Jul. 24, 2025

Related U.S. Application Data
(63) Continuation of application No. PCT/JP2024/004001, filed on Feb. 7, 2024.

(30) Foreign Application Priority Data
Feb. 13, 2023 (JP) 2023-020206

(51) Int. Cl. H01J 37/32

(52) U.S. Cl. CPC H01J 37/32715; H01J 37/32091; H01J 37/32642; H01J 2237/2007; H01J 2237/204; H01J 2237/24495; H01J 2237/24578

(57) ABSTRACT

A substrate processing apparatus includes a substrate support including an electrostatic chuck, a transfer arm that transfers the substrate into the chamber, a sensor disposed at the transfer arm and measures a distance from the sensor to the substrate and a distance from the sensor to a reference surface set at the substrate support, and processing circuitry that acquires a first distance from the sensor to the substrate and a second distance from the sensor to the reference surface before adsorption and controls the direct-current voltage to be applied to the electrostatic electrode based on the amount of change in the warpage amount of the substrate.

### CROSS-REFERENCE TO RELATED APPLICATIONS

This application is a bypass continuation application of international application No. PCT/JP2024/004001 having an international filing date of Feb. 7, 2024 and designating the United States, the international application being based upon and claiming the benefit of priority from Japanese Patent Application No. 2023-020206, filed on Feb. 13, 2023, the entire contents of each are incorporated herein by reference.

### TECHNICAL FIELD

The present disclosure relates to a substrate processing apparatus and a substrate processing method.

### BACKGROUND

For example, PTL 1 proposes a method of determining wear of a consumable component in a semiconductor processing apparatus. A chamber includes therein a reference component that does not wear and a consumable component that wears during an operation of the chamber, and a sensor measures a first distance from the sensor to a surface of the consumable component when a transfer arm moves near the consumable component and measures a second distance from the sensor to a surface of the reference component when the transfer arm moves near the reference component. A controller determines an amount of wear of the consumable component based on the first distance and the second distance.

### CITATION LIST

### Patent Documents

PTL 1: JP2017-50535A

### SUMMARY

The present disclosure provides a technique that can quantitatively measure an adsorption force of a substrate.

According to an aspect of the present disclosure, provided is a substrate processing apparatus including: a chamber configured to process a substrate, a substrate support disposed in the chamber and including an electrostatic chuck that includes an electrostatic electrode and a substrate support surface, the substrate support being configured to electrostatically adsorb the substrate to the substrate support surface by applying a direct-current voltage to the electrostatic electrode, a transfer arm configured to transfer the substrate into the chamber, a sensor disposed at the transfer arm, the sensor being configured to measure a distance from the sensor to the substrate and a distance from the sensor to a reference surface set at the substrate support, and a control device configured to acquire a first distance from the sensor to the substrate before adsorbing and a second distance from the sensor to the reference surface before adsorbing, which are measured by the sensor, and calculate a first difference that is a difference between the first distance and the second distance, acquire a third distance from the sensor to the substrate after adsorbing and a fourth distance from the sensor to the reference surface after adsorbing, which are measured by the sensor, and calculate a second difference that is a difference between the third distance and the fourth distance, calculate an amount of change in a warpage amount of the substrate based on the first difference and the second difference, and control the direct-current voltage to be applied to the electrostatic electrode based on the amount of change in the warpage amount of the substrate.

According to one aspect, an adsorption force of a substrate can be quantitatively measured.

### BRIEF DESCRIPTION OF DRAWINGS

FIG. 1 is a view illustrating an example of a plasma processing system according to an embodiment.

FIG. 2 is a schematic cross-sectional view illustrating an example of the plasma processing apparatus according to the embodiment.

FIG. 3A is a bottom view illustrating a disposition example of a fork and a sensor according to the embodiment.

FIG. 3B is a bottom view illustrating a disposition example of the fork and the sensor according to the embodiment.

FIG. 4 is a view illustrating measurement of heights of an edge ring and a substrate by the sensor.

FIG. 5 is a view illustrating the measurement of the heights of the edge ring and the substrate by the sensor.

FIG. 6A is a view illustrating an example of measuring the heights of the edge ring and the substrate by the sensor before and after adsorption.

FIG. 6B is a view illustrating an example of measuring the heights of the edge ring and the substrate by the sensor before and after adsorption.

FIG. 7 is a view illustrating an example of a difference between measured values before and after adsorption illustrated in FIG. 6.

FIG. 8 is a flowchart illustrating an example of a substrate processing method (including measurement processing) according to the embodiment.

FIG. 9 is an example of a correlation graph used for controlling a direct-current voltage in the substrate processing method in FIG. 8.

FIG. 10 is a flowchart illustrating an example of a transfer processing method for a jig edge ring according to the embodiment.

FIG. 11A is a view illustrating transfer of the jig edge ring in FIG. 10.

FIG. 11B is a view illustrating the transfer of the jig edge ring in FIG. 10.

FIG. 11C is a view illustrating the transfer of the jig edge ring in FIG. 10.

FIG. 11D is a view illustrating the transfer of the jig edge ring in FIG. 10.

FIG. 11E is a view illustrating the transfer of the jig edge ring in FIG. 10.

FIG. 11F is a view illustrating the transfer of the jig edge ring in FIG. 10.

FIG. 11G is a view illustrating the transfer of the jig edge ring in FIG. 10.

FIG. 11H is a view illustrating the transfer of the jig edge ring in FIG. 10.

FIG. 12 is a flowchart illustrating an example of a transfer processing method for the edge ring according to a modification of the embodiment.

FIG. 13A is a view illustrating transfer of the edge ring in FIG. 12.

FIG. 13B is a view illustrating the transfer of the edge ring in FIG. 12.

FIG. 13C is a view illustrating the transfer of the edge ring in FIG. 12.

FIG. 13D is a view illustrating the transfer of the edge ring in FIG. 12.

### DETAILED DESCRIPTION

Hereinafter, embodiments for implementing the present disclosure will be described with reference to the drawings. In the respective drawings, the same components will be denoted by the same reference numerals, and overlapping descriptions thereof may be appropriately omitted.

### Plasma Processing System

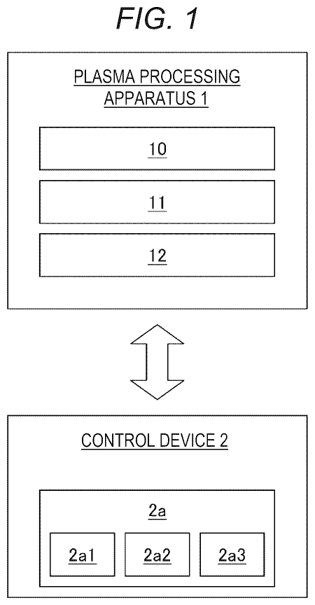

FIG. 1 is a diagram illustrating an example of a configuration of a plasma processing system. In one embodiment, the plasma processing system includes a plasma processing apparatus 1 and a control device 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 is an example of a chamber for processing a substrate. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting a substrate. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Furthermore, various types of plasma generators, including an alternating current (AC) plasma generator and a direct current (DC) plasma generator, may be used. In one embodiment, an AC signal (AC power) used by the AC plasma generator has a frequency within a range from 100 kHz to 10 GHz. The AC signal therefore includes a radio frequency (RF) signal and a microwave signal. In one embodiment, the RF signal has a frequency within a range from 100 kHz to 150 MHz.

The control device 2 processes a computer-executable instruction for instructing the plasma processing apparatus 1 to execute various steps to be described herein below. The control device 2 may be configured to control respective elements of the plasma processing apparatus 1 to execute the various steps to be described herein below. In an embodiment, a part or all of the control device 2 may be included in the plasma processing apparatus 1. The control device 2 may include a processor 2a1, a storage 2a2, and a communication interface 2a3. The control device 2 is implemented by, for example, a computer 2a. The processor 2a1 may be configured to read a program from the storage unit 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

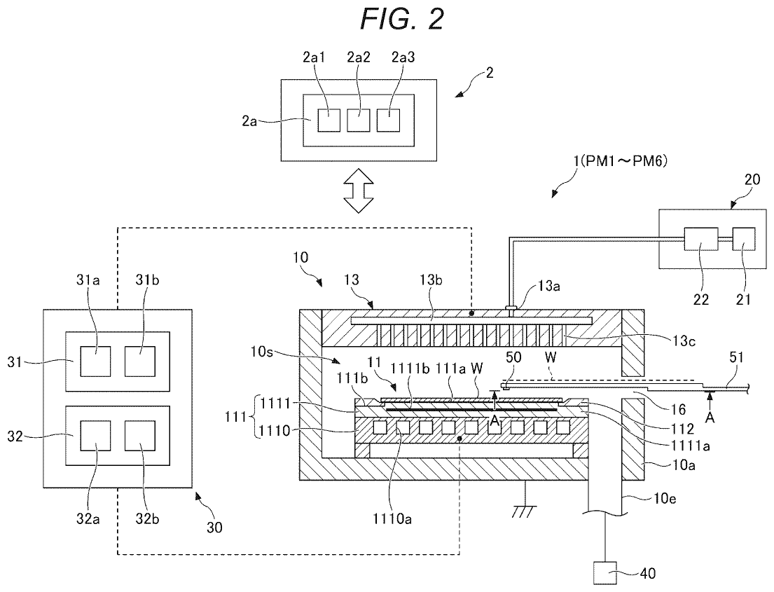

Hereinafter, an example of a configuration of a capacitively-coupled plasma processing apparatus as an example of the plasma processing apparatus 1 will be described. FIG. 2 is a diagram illustrating the example of the configuration of the capacitively-coupled plasma processing apparatus.

The capacitively-coupled plasma processing apparatus 1 includes the plasma processing chamber 10, the gas supply 20, a power source 30, and the exhaust system 40. The plasma processing apparatus 1 further includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly. The main body 111 has a central region 111a for supporting a substrate W, and an annular region 111b for supporting the ring assembly. A wafer is an example of the substrate W. The annular region 111b of the main body 111 surrounds the central region 111a of the main body 111 in a plan view. The substrate Wis disposed on the central region 111a of the main body 111, and the ring assembly is disposed on the annular region 111b of the main body 111 to surround the substrate W on the central region 111a of the main body 111. Therefore, the central region 111a is also called a substrate support surface for supporting the substrate W, and the annular region 111b is also called a ring support surface for supporting the ring assembly.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The electrostatic electrode 1111b is connected to a direct-current power supply (not illustrated) connected to apply a direct-current voltage for adsorbing the substrate W to the electrostatic chuck 1111. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the ring assembly may be disposed on the annular electrostatic chuck or the annular insulating member, or may be disposed on both the electrostatic chuck 1111 and the annular insulating member. Further, at least one RF/DC electrode coupled to the RF power source 31 and/or the DC power source 32 to be described later may be disposed in the ceramic member 1111a. In this case, at least one RF/DC electrode functions as the lower electrode. When a bias RF signal and/or DC signal, which will be described later, are supplied to the at least one RF/DC electrode, the RF/DC electrode is also called a bias electrode. The conductive member of the base 1110 and at least one RF/DC electrode may function as a plurality of lower electrodes. The electrostatic electrode 1111b may instead function as the lower electrode. Accordingly, the substrate support 11 includes at least one lower electrode.

The ring assembly includes one or more annular members. In one embodiment, the one or a plurality of annular members include one or a plurality of edge rings 112 and at least one cover ring. Each edge ring 112 is made of an electrically conductive material or an insulating material, and the cover ring is made of an insulating material.

Further, the substrate support 11 may include a temperature control module configured to adjust at least one of the electrostatic chuck 1111, the ring assembly, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed in the base 1110, and one or more heaters are disposed in the ceramic member 1111a of the electrostatic chuck 1111. The substrate support 11 may further include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. The shower head 13 further includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. The flow rate controller 22 may include, for example, a mass flow controller or a pressure-controlled flow rate controller. Further, the gas supply 20 may include at least one flow rate modulation device that modulates or pulses a flow rate of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Plasma is thus generated from the at least one processing gas supplied into the plasma processing space 10s. Accordingly, the RF power source 31 may function as at least a part of the plasma generator 12. Supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is coupled to the at least one lower electrode via the at least one impedance matching circuit and configured to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

The power source 30 may include the DC power source 32 coupled to the plasma processing chamber 10. The DC power source 32 includes a first DC generator 32a and a second DC generator 32b. In one embodiment, the first DC generator 32a is connected to at least one lower electrode to generate a first DC signal. The generated first DC signal is applied to the at least one lower electrode. In one embodiment, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. The sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected, for example, to a gas exhaust port 10e disposed at a bottom of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

A loading/unloading port 16 provided in the sidewall 10a of the plasma processing chamber 10 is openable and closable by a gate valve (not illustrated). When the substrate W is loaded, the gate valve is opened. Subsequently, the substrate W is loaded into the plasma processing chamber 10 by a transfer arm 51. Thereafter, raising and lowering of a raising/lowering pin (not illustrated) and the like is performed, and the substrate Wis placed on the electrostatic chuck 1111. Subsequently, after the transfer arm 51 is unloaded, the gate valve is closed to seal the plasma processing chamber 10, and pressure in the plasma processing chamber 10 is reduced to a predetermined vacuum level by the exhaust system 40. In addition, a direct-current voltage is applied to the electrostatic electrode 1111b of the electrostatic chuck 1111, and accordingly, the substrate W is adsorbed and held at the substrate support surface (central region 111a) of the electrostatic chuck 1111 by an electrostatic force.

### Transfer Arm

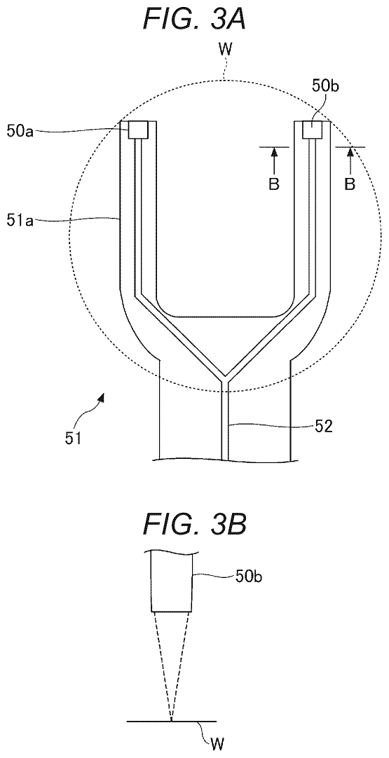

Next, a disposition of a fork 51a of the transfer arm 51 and a sensor 50 will be described with reference to FIGS. 3A and 3B. FIG. 3A is a view when a lower surface of the transfer arm 51 is viewed from a plane A-A in FIG. 2, and illustrates an example of the disposition of the fork 51a at a distal end and the sensor 50. The transfer arm 51 is implemented by, for example, a multi-joint arm, and includes the fork 51a on the distal end side. The fork 51a has a bifurcated shape having a lateral width smaller than a diameter of the substrate W. When the transfer arm 51 is raised and lowered, the fork 51a is raised and lowered, and when the transfer arm 51 is rotated, extended, or retracted, the fork 51a moves in a horizontal direction.

A sensor 50a is provided at a lower surface of one of bifurcated distal ends of the fork 51a, and a sensor 50b is attached to a lower surface of the other. The sensors 50a and 50b are connected to an optical fiber 52 to transmit measured values of the sensors 50a and 50b to the control device 2 through the optical fiber 52. The sensors 50a and 50b may be disposed not on the distal end side of the fork 51a but on a proximal end side. The optical fiber 52 and the sensors 50a and 50b are disposed along the lower surface of the transfer arm 51 so as not to interfere with holding of the substrate W by the transfer arm 51.

FIG. 3B is a view when the sensor 50b is viewed from a plane B-B in FIG. 3A. The sensor 50b measures a distance from the sensor 50b to a target point (in the example of FIG. 3B, the substrate W). A measured value of the distance to the target point measured by the sensor 50b is transmitted to the control device 2, and control based on the measured value is performed by the control device 2. The sensor 50a has a structure and a function identical to the sensor 50b. The sensors 50a and 50b will also be collectively referred to as the sensor 50. Only one sensor 50 may be disposed at the fork, or three or more sensors 50 may be disposed.

As a distance measurement method using the sensor 50, a method that can perform non-contact measurement in a vacuum atmosphere, for example, a method based on light is adopted. In this case, for example, the sensor 50 irradiates a target object with distance measurement light and receives reflected light, and the control device 2 measures the distance from the sensor 50 to the target point based on a light reception result by the sensor 50.

A more specific example of the distance measurement method using the sensor 50 is to use a white light confocal displacement sensor. The white light confocal displacement sensor is a sensor in which, among light transmitted through a multi-lens, light having a wavelength focused on a surface of a measurement target is transmitted, detected by a spectrometer, and output as a distance or displacement. When the sensor 50 adopts the white light confocal method, for example, light supplied from a light source such as an LED (not illustrated) is emitted from the sensor 50 to the target object such that each wavelength in the light is focused at a different height. Then, only the light having the wavelength focused on the target object is received, as reflected light, by the control device 2 through the sensor 50. The control device 2 calculates the distance from the sensor 50 to the target point based on the wavelength of the received light. The white light confocal method is merely an example, and any method may be used as long as the distance can be measured with desired accuracy (for example, a resolution in a height direction is about 15 μm or less).

The sensor 50 and the control device 2 may be directly connected to each other through the optical fiber 52, or may be indirectly connected to each other through a unit controller (not illustrated). The distance measurement light or the reflected light measured by the sensor 50 is transmitted from the sensor 50 to the control device 2 or the unit controller through the optical fiber 52.

### Measurement by Sensor

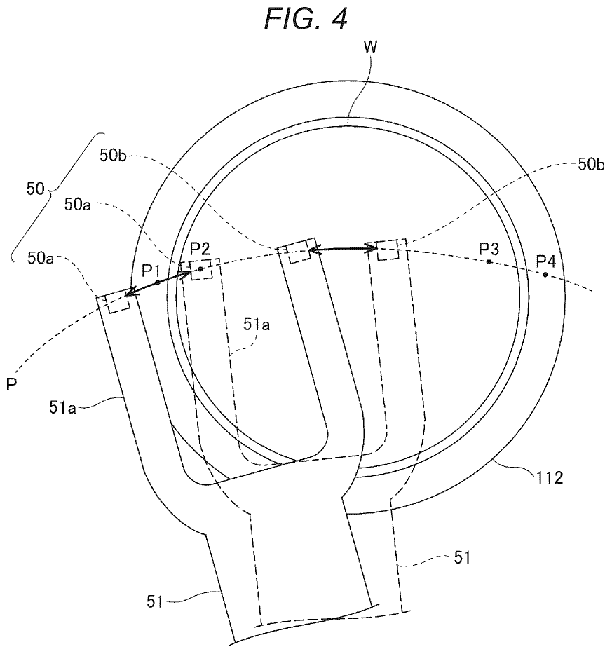

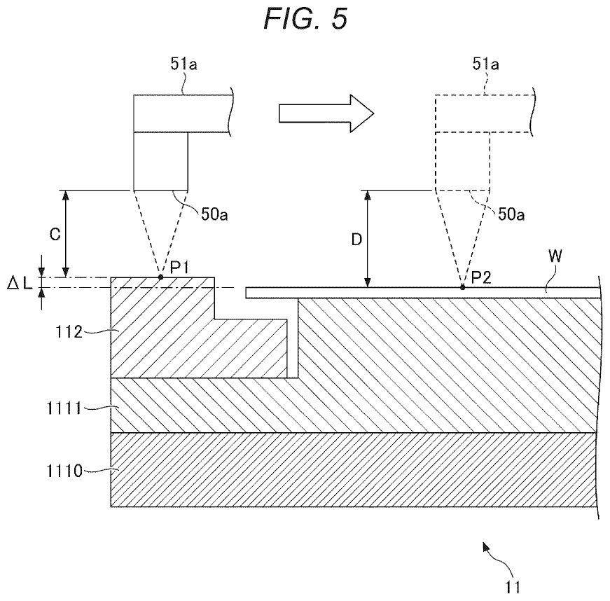

Measurement of distances to the edge ring 112 and the substrate W (heights) by the sensor 50 will be described with reference to FIGS. 4 and 5. FIGS. 4 and 5 are views illustrating the measurement of the heights of the edge ring 112 and the substrate W by the sensor 50.

When measuring the distance to the edge ring 112 by the sensor 50, the control device 2 may control the transfer arm 51 such that the fork 51a moves to move the sensor 50a in a predetermined direction, as illustrated in FIG. 4. The predetermined direction may be, for example, a direction (a left-right direction in FIG. 4) crossing a boundary between the edge ring 112 and the substrate W in a plan view and intersecting an insertion/extraction direction (an up-down direction in FIG. 4) of the fork 51a. In addition, the predetermined direction may be the insertion/extraction direction of the fork 51a, or may be another direction. That is, the distances to the edge ring 112 and the substrate W (heights) can be measured by the sensor 50 according to movement of the fork 51a crossing the boundary between the edge ring 112 and the substrate W.

For example, as illustrated in FIG. 4, the fork of the transfer arm 51 is moved in the left-right direction in FIG. 4 to pass through a trajectory P, and a distance C (see FIG. 5) from the sensor 50a to a surface of the edge ring 112 is measured by the sensor 50a at a point Pl on the edge ring 112. In addition, the fork is further moved, and a distance D (see FIG. 5) from the sensor 50a to a surface of the substrate W is measured by the sensor 50a at a point P2 on the substrate W. The control device 2 calculates a difference ΔL (=D−C) in the heights between the edge ring 112 and the substrate W based on the measured values (distances C and D). In this way, the control device 2 can calculate the difference ΔL (=D−C) in the heights between the edge ring 112 and the substrate W based on the measured values (distances C and D).

As illustrated in FIG. 4, the fork of the transfer arm 51 may be moved further in the left-right direction, and the distance D (see FIG. 5) from the sensor 50b to the surface of the substrate W may be measured by the sensor 50b at a point P3 on the substrate W. In addition, the distance C (see FIG. 5) from the sensor 50b to the surface of the edge ring 112 may be measured by the sensor 50b at a point P4 on the edge ring 112. In this way, the control device 2 may acquire the measured values (distances C and D) at the plurality of measurement positions and calculate the difference ΔL (=D−C) in the heights between the edge ring 112 and the substrate W at the plurality of measurement positions based on the plurality of measured values.

The surface of the edge ring 112 is an example of a reference surface set at the substrate support 11. That is, the control device 2 calculates the difference ΔL that indicates a distance from the reference surface to the substrate W. When there are a plurality of measurement positions, the control device 2 calculates the difference ΔL indicating the distance from the reference surface to the substrate W for each measurement point. Then, the control device 2 generates a distribution of the difference ΔL in the heights between the reference surface and the substrate W in the crossing direction of the edge ring 112 for the plurality of measurement points, based on each difference ΔL obtained from a plurality of calculation results and positional information on each measurement point. The measurement position of each measurement point can be calculated based on angles and dimensions of constituent members of the transfer arm 51 when the distances C and D are measured.

In the example in FIG. 5, the difference ΔL indicating the distance from the reference surface to the substrate W in a state in which the substrate W has no warpage is illustrated.

However, in general, the actual substrate W has warpage. Thus, in order to reduce variations caused by individual differences in the warpage amount of the substrate W, it is desirable to determine a reference substrate W in advance and use the substrate W as a jig substrate Wa at the time of measurement.

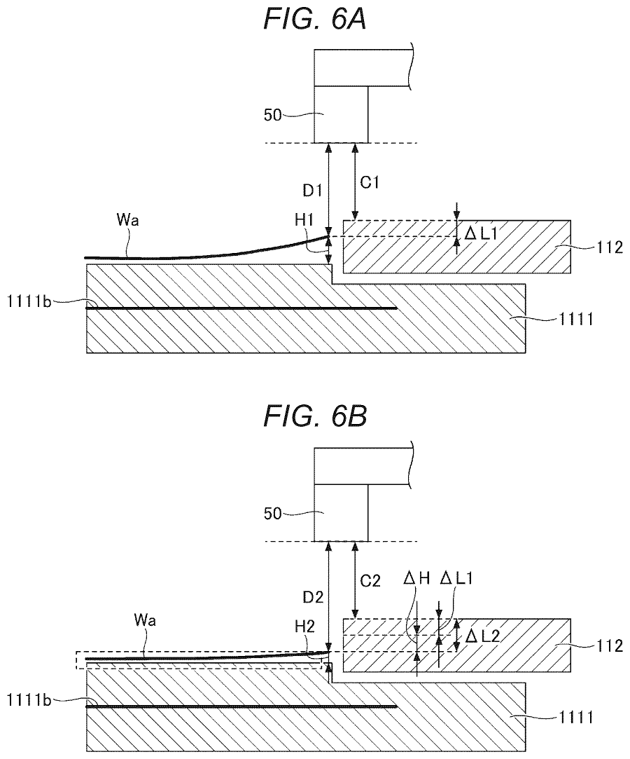

An example of measuring the distances to the edge ring 112 and the substrate W (heights) by the sensor 50 using the jig substrate Wa will be described with reference to FIGS. 6A and 6B. FIG. 6A shows a state before adsorption in which the direct-current voltage for adsorbing the substrate is not applied to the electrostatic electrode 1111b of the electrostatic chuck 1111. The jig substrate Wa before adsorption is warped upward at an outer peripheral portion. The warpage amount at the outer peripheral portion of the jig substrate Wa before adsorption is denoted by H1.

FIG. 6B is a state after the direct-current voltage for adsorbing the substrate is applied to the electrostatic electrode 1111b. The jig substrate Wa after adsorption has, due to an adsorption force, a smaller upward warpage amount at the outer peripheral portion than that before adsorption. When the warpage amount at the outer peripheral portion of the jig substrate Wa after adsorption is denoted by H2, a relationship of H2<H1 is satisfied. That is, an amount of change between the warpage amounts H1 and H2 is an indicator showing the adsorption force, the adsorption force of the substrate can be quantitatively measured based on the amount of change between the warpage amounts Hl and H2, and an adsorption state of the substrate W can be determined.

As illustrated in FIG. 6A, the control device 2 acquires a first difference ALI that is a difference between a distance D1 from the sensor 50 to the jig substrate Wa before adsorption and a distance C1 from the sensor 50 to the surface of the edge ring 112 before adsorption, which are measured by the sensor 50. The distance D1 is an example of a first distance from the sensor 50 to the substrate before adsorption. The distance C1 is an example of a second distance from the sensor 50 to the reference surface before adsorption.

As illustrated in FIG. 6B, the control device 2 acquires a second difference AL2 that is a difference between a distance D2 from the sensor 50 to the jig substrate Wa after adsorption and a distance C2 from the sensor 50 to the surface of the edge ring 112 after adsorption, which are measured by the sensor 50. The distance D2 is an example of a third distance from the sensor 50 to the substrate after adsorption. The distance C2 is an example of a fourth distance from the sensor 50 to the reference surface after adsorption.

The first distance is a distance from the sensor 50 to the outer peripheral portion of the jig substrate Wa (substrate W) before adsorption, and the third distance is a distance from the sensor 50 to the outer peripheral portion of the jig substrate Wa (substrate W) after adsorption. The outer peripheral portion of the jig substrate Wa (substrate W) is an annular region of about 140 mm to 150 mm in a radial direction from a center of the jig substrate Wa (substrate W). A region of the edge ring 112 is an annular region of about 155 mm to 165 mm in the radial direction from the center of the jig substrate Wa (the substrate W).

The control device 2 calculates the amount of change in the warpage amount of the jig substrate Wa based on the first difference ΔL1 and the second difference ΔL2. That is, the control device 2 calculates a difference between the second difference ΔL2 and the first difference ΔL1 as an amount of change ΔH (=H1−H2) in the warpage amount of the jig substrate Wa before and after adsorption.

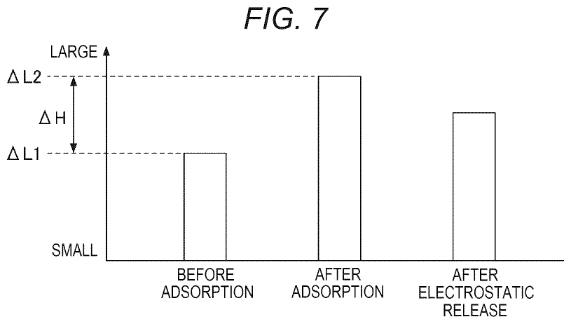

FIG. 7 is a view illustrating an example of the amount of change ΔH in the warpage amount calculated by the control device 2. In a state before adsorption illustrated in FIG. 6A, the distance ΔL1 from the reference surface (the surface of the edge ring 112) to the outer peripheral portion (outermost periphery) of the jig substrate Wa is smaller than the distance ΔL2 from the reference surface (the surface of the edge ring 112) to the outer peripheral portion of the jig substrate Wa after adsorption illustrated in FIG. 6B. That is, the amount of change ΔH in the warpage amount illustrated in FIG. 7 quantitatively represents the adsorption force of the substrate W, and as the adsorption force decreases, the amount of change ΔH in the warpage amount decreases. After electrostatic release (dechucking), the warpage of the jig substrate Wa becomes large again.

The control device 2 can determine the adsorption state of the substrate W based on the calculated amount of change ΔH in the warpage amount of the jig substrate Wa before and after adsorption. The control device 2 may also determine the adsorption state of the substrate W based on an RF cumulative time and the calculated amount of change ΔH in the warpage amount of the jig substrate Wa before and after adsorption. The RF cumulative time is a cumulative time during which RF power is supplied from the RF power source 31 into the plasma processing chamber 10.

The control device 2 may control the direct-current voltage to be applied to electrostatic electrode 1111b based on the amount of change ΔH in the warpage amount of the jig substrate Wa. For example, the control device 2 stores, in the storage 2a2 in advance, correlation information (see FIG. 9) among the amount of change ΔH in the warpage amount of the jig substrate Wa, the RF cumulative time, and the direct-current voltage to be applied to electrostatic electrode 1111b. The control device 2 may refer to the storage 2a2 and perform control to increase the direct-current voltage to be applied to the electrostatic electrode 1111b when it is determined that the amount of change ΔH in the warpage amount of jig substrate Wa is lower than a threshold value based on the RF cumulative time and the calculated amount of change ΔH in the warpage amount of the substrate.

After performing control to increase the direct-current voltage to be applied to the electrostatic electrode 1111b, the control device 2 may determine that the substrate support 11 is required to be replaced when it is determined that the calculated amount of change ΔH in the warpage amount of the jig substrate Wa (substrate W) does not exceed the threshold value. For example, in the example in FIG. 9, when ΔH falls below a threshold value th when the RF cumulative time is t, the control device 2 performs control to increase the direct-current voltage to be applied to the electrostatic electrode 1111b from 300 V to 400 V. Accordingly, the amount of change ΔH in the warpage amount of the jig substrate Wa (substrate W) is controlled to exceed the threshold value as illustrated at t in FIG. 9, and the adsorption state of the substrate is normally controlled. However, the control device 2 may determine that the substrate support 11 is required to be replaced when it is determined that the amount of change ΔH in the warpage amount of the jig substrate Wa (the substrate W) does not exceed the threshold value even when the control is performed to increase the direct-current voltage to be applied to the electrostatic electrode 1111b from 300 V to 400 V.

### Substrate Processing Method Including Measurement Processing

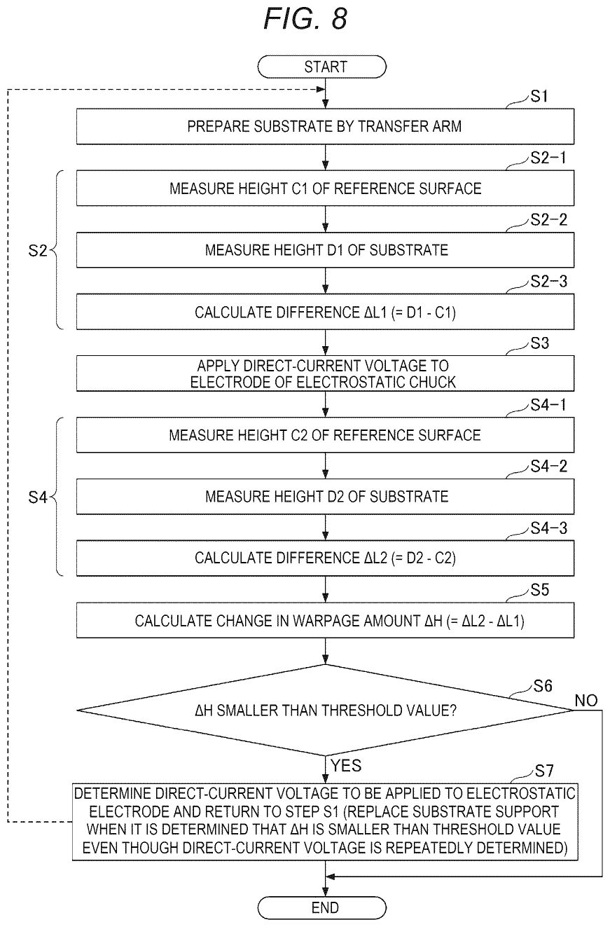

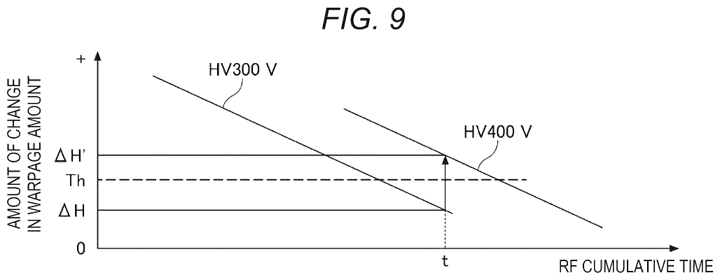

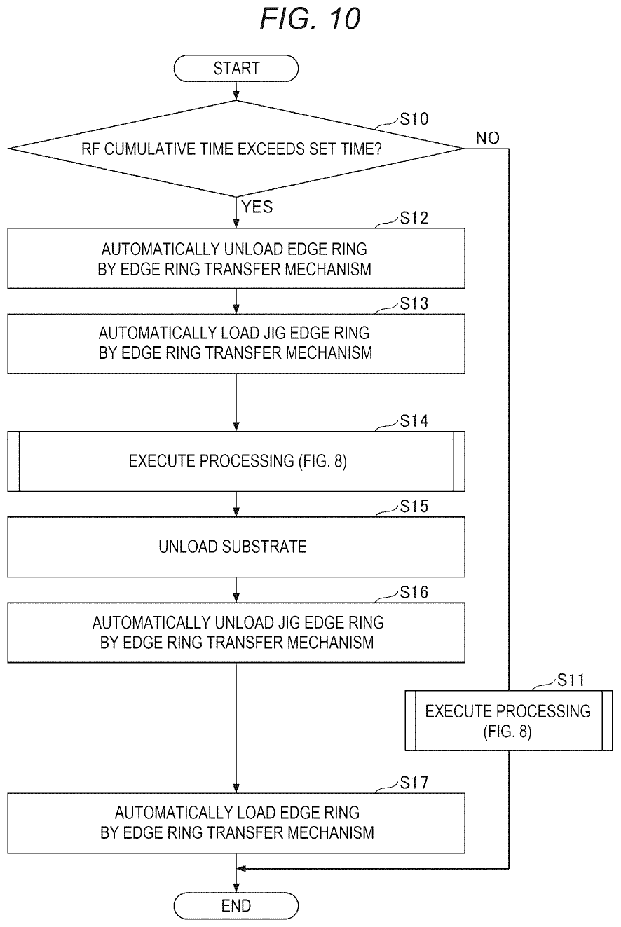

Next, a substrate processing method (including measurement processing) according to one embodiment will be described with reference to FIGS. 8 and 9. FIG. 8 is a flowchart illustrating an example of the substrate processing method that includes the measurement processing according to the embodiment. FIG. 9 is an example of a correlation graph used for controlling a direct-current voltage in the substrate processing method in FIG. 8. The measurement processing is performed during processing of the product substrate W (for example, every 100 hours) using the jig substrate Wa. In the processing, measurement is performed using the jig substrate Wa, and alternatively may be performed using the product substrate W.

When the processing is started, in step S1, the control device 2 inserts the transfer arm 51 from the loading/unloading port 16, and places and prepares the jig substrate Wa held by the transfer arm 51 on the substrate support surface (central region 111a) of the substrate support 11.

Next, in step S2, the control device 2 controls measurement processing of S2-1, S2-2, and S2-3 for the jig substrate Wa before adsorption. Either step S2-1 or S2-2 may be performed first.

In step S2-1, the sensor 50 measures the distance (height) C1 (see FIG. 6A) from the sensor 50 to the reference surface (the surface of the edge ring 112) when the transfer arm 51 moves on the edge ring 112 around the jig substrate Wa. Next, in step S2-2, the sensor 50 measures the distance (height) D1 (see FIG. 6A) from the sensor 50 to the outer peripheral portion of the jig substrate Wa before adsorption when the transfer arm 51 moves on the outer peripheral portion of the jig substrate Wa. The control device 2 calculates the difference ΔL1 between the measured distances D1 and C1.

Next, in step S3, the control device 2 applies the direct-current voltage to the electrostatic electrode 1111b of the electrostatic chuck 1111 to electrostatically adsorb the jig substrate Wa to the electrostatic chuck 1111.

Next, in step S4, the control device 2 controls measurement processing of S4-1, S4-2, and S4-3 for the jig substrate Wa after adsorption. Either step S4-1 or S4-2 may be performed first.

In step S4-1, the sensor 50 measures the distance (height) C2 (see FIG. 6B) from the sensor 50 to the reference surface when the transfer arm 51 moves on the edge ring 112 around the jig substrate Wa. Next, in step S4-2, the sensor 50 measures the distance (height) D2 (see FIG. 6B) from the sensor 50 to the outer peripheral portion of the jig substrate Wa after adsorption when the transfer arm 51 moves on the outer peripheral portion of the jig substrate Wa. The control device 2 calculates the difference ΔL2 between the measured distances D2 and C2.

Next, in step S5, the control device 2 calculates, as the amount of change ΔH in the warpage amount of the jig substrate Wa, a difference between the distance ΔL1 from the reference surface to the height of the outer peripheral portion of the jig substrate Wa before adsorption, and the distance ΔL2 from the reference surface to the height of the outer peripheral portion of the jig substrate Wa after adsorption. For example, the amount of change ΔH in the warpage amount is calculated by subtracting ΔL1 from ΔL2 (i.e., ΔH =ΔL2−ΔL1). It is illustrated that the adsorption force of the substrate decreases as the calculated amount of change ΔH in the warpage amount decreases. Accordingly, the adsorption force of the substrate can be quantitatively measured.

Next, in step S6, the control device 2 determines whether the calculated amount of change ΔH in the warpage amount is smaller than the threshold value. When it is determined that the calculated amount of change ΔH in the warpage amount is equal to or greater than the threshold value, the control device 2 determines that the adsorption state of the substrate is normal and ends the processing.

When it is determined in step S6 that the calculated amount of change ΔH in the warpage amount is smaller than the threshold value, the control device 2 determines that the adsorption state of the substrate is abnormal and the adsorption force of the substrate decreases, and proceeds to step S7 to determine the direct-current voltage to be applied to the electrostatic electrode 1111b.

FIG. 9 is an example of a graph illustrating the correlation information with the RF cumulative time on a horizontal axis, the difference ΔH representing the adsorption force (the amount of change in the warpage amount of the substrate) on a vertical axis, and the direct-current voltage to be applied to the electrostatic electrode 1111b (i.e., 300V to 400V). The correlation information may be stored in advance in the storage 2a2.

As the RF cumulative time increases, even when the same direct-current voltage is applied to the electrostatic electrode 1111b, the adsorption force of the substrate decreases due to, for example, consumption of the electrostatic chuck 1111 or the edge ring 112. Thus, the control device 2 determines the direct-current voltage to be applied to electrostatic electrode 1111b based on the calculated amount of change in the warpage amount of the substrate by referring to the storage 2a2 that stores the correlation information on the amount of change ΔH in the warpage amount of the substrate, the RF cumulative time, and the direct-current voltage to be applied to the electrostatic electrode 1111b (step S7 in FIG. 8). Then, after determining the direct-current voltage, the measurement processing of steps S1 to S6 is performed again. When it is determined that the amount of change ΔH in the warpage amount calculated during the RF cumulative time at that time point is equal to or greater than the threshold value, the control device 2 determines that the adsorption state of the substrate is normal. For example, as illustrated in FIG. 9, it is assumed that the RF cumulative time is t, and the control device 2 determines to change the direct-current voltage to be applied to the electrostatic electrode 1111b from 300 V to 400 V based on the calculated amount of change in the warpage amount of the substrate by referring to the storage 2a2. In the example in FIG. 9, since an amount of change ΔH' in the warpage amount calculated during the RF cumulative time at that time point is equal to or greater than a threshold value Th, it is determined that the adsorption state of the substrate is normal. On the other hand, when it is determined that the amount of change ΔH in the warpage amount of the jig substrate Wa calculated does not exceed the threshold value even when the determination and control of the direct-current voltage to be applied to the electrostatic electrode 1111b are repeated, it is determined that the substrate support 11 is required to be replaced.

### First Method for Applying Reference Surface: Transferring Jig Edge Ring

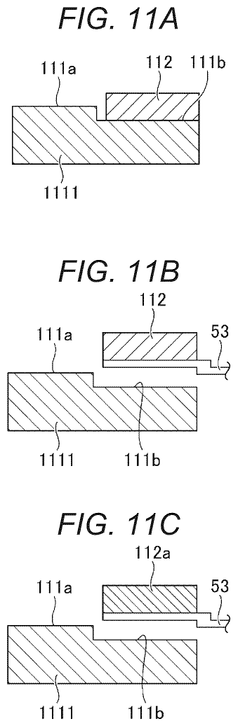

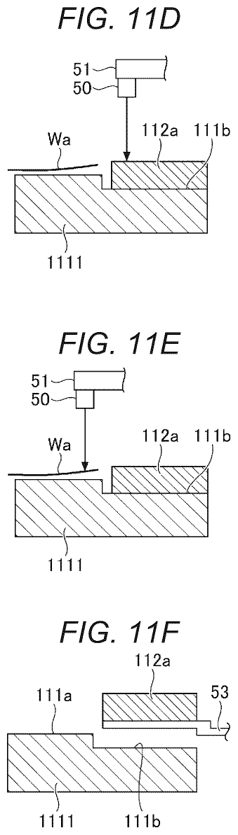

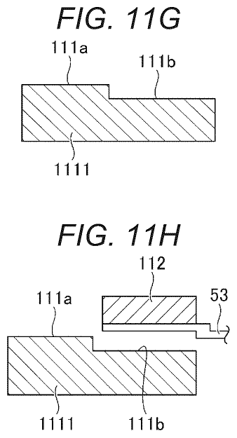

Next, a jig edge ring transfer processing method in the substrate processing (including the measurement processing) according to one embodiment will be described with reference to FIGS. 10 and 11A to 11H. FIG. 10 is a flowchart illustrating an example of transfer processing for a jig edge ring 112a according to the embodiment. FIGS. 11A to 11H are views illustrating transfer of the jig edge ring 112a in FIG. 10. Since the edge ring 112 is consumed by the substrate processing, the reference surface varies. Therefore, the jig edge ring may be a new edge ring, or may be a non-consumed member that is a member having the same shape as the new edge ring. That is, the jig edge ring may be replaced with a new jig edge ring.

When the processing is started, in step S10, the control device 2 determines whether the RF cumulative time exceeds a preset time. When it is determined that the RF cumulative time does not exceed the set time, the control device 2 proceeds to step S11, executes the substrate processing (including the measurement processing) in FIG. 8 described above, and ends the present processing.

On the other hand, when it is determined that the calculated RF cumulative time exceeds the set time, the control device 2 proceeds to step S12 and automatically unloads the edge ring 112 by an edge ring transfer mechanism (i.e., edge ring transferrer). The edge ring 112 is held in a suitably stockable container. The edge ring transfer mechanism is a transfer device that can transfer the edge ring 112.

At this time, the edge ring 112 in FIG. 11A is placed on the ring support surface (annular region 111b). From this state, the edge ring is lifted by a pin (not illustrated), delivered to an edge ring transfer mechanism 53, and unloaded from the loading/unloading port 16 as illustrated in FIG. 11B.

Next, in step S13, the edge ring transfer mechanism 53 automatically loads the jig edge ring 112a from the loading/unloading port 16 (see FIG. 11C) and transfers the jig edge ring 112a to the pin (not illustrated). When the pin (not illustrated) is lowered, the jig edge ring 112a is placed on the ring support surface (annular region 111b), as illustrated in FIG. 11D.

Next, in step S14, the control device 2 executes the substrate processing (including the measurement processing) in FIG. 8. In step S11, the surface (upper surface) of the edge ring 112 is the reference surface, but in step S14, a surface (upper surface) of the jig edge ring 112a is the reference surface. Since the edge ring 112 is exposed to plasma and consumed, the surface of the edge ring 112 serves as the reference surface until the RF cumulative time exceeds the set time. Meanwhile, after the RF cumulative time exceeds the set time, the surface of the jig edge ring 112a serves as the reference surface instead of the consumed edge ring 112.

As illustrated in FIG. 11D, the processing in FIG. 8 is executed using the surface of the jig edge ring 112a as the reference surface, and the amount of change in the warpage amount of the substrate is calculated (see FIGS. 11D and 11E). Accordingly, even when the RF cumulative time exceeds the set time, the reference surface can be fixed by replacing with the jig edge ring 112a which has the same height as the new edge ring 112 or whose surface can be maintained at a predetermined height to a certain extent. Accordingly, even when the edge ring 112 is consumed, measurement accuracy of a measured value, using the sensor 50, of the warpage amount before and after the substrate is adsorbed can be maintained. Accordingly, it is possible to determine a decrease in the adsorption force based on the amount of change in the warpage amount.

When the processing in step S14 ends, in step S15, the control device 2 unloads the jig substrate Wa. Next, in step S16, the control device 2 automatically unloads the jig edge ring 112a by the edge ring transfer mechanism 53 (see FIGS. 11F and 11G).

Next, in step S17, the control device 2 loads the edge ring 112 unloaded in step S12 again by the edge ring transfer mechanism 53, disposes the edge ring 112 on the ring support surface (annular region 111b) (see FIG. 11H), and ends the processing.

According to the first method for applying the reference surface, an amount of consumption of the edge ring 112 is estimated based on the RF cumulative time, and when the RF cumulative time exceeds the set time, the surface of the jig edge ring 112a is used as the reference surface. That is, when measuring the warpage amount of the jig substrate Wa, the measurement is performed after replacing with the new edge ring or the jig edge ring 112a that can maintain a certain fixed height. Accordingly, the adsorption force of the substrate can be quantitatively measured.

### Second Method for Applying Reference Surface: Transferring Edge Ring

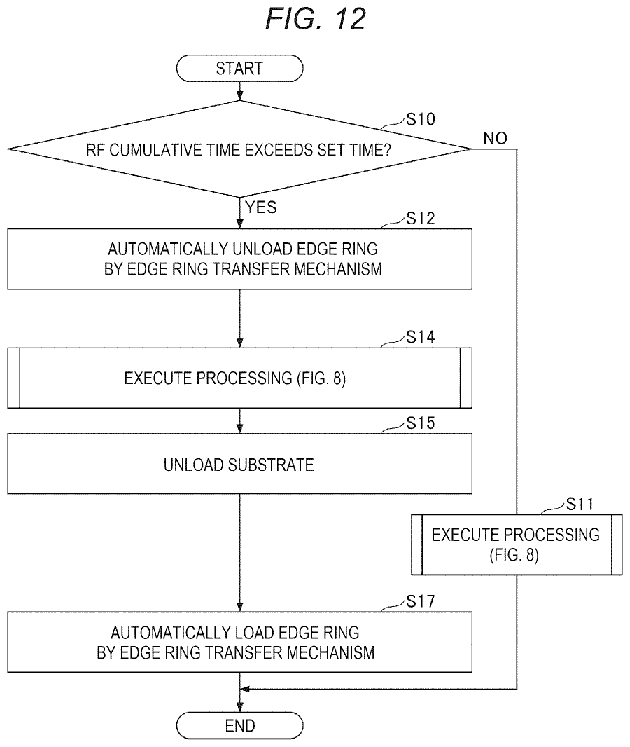

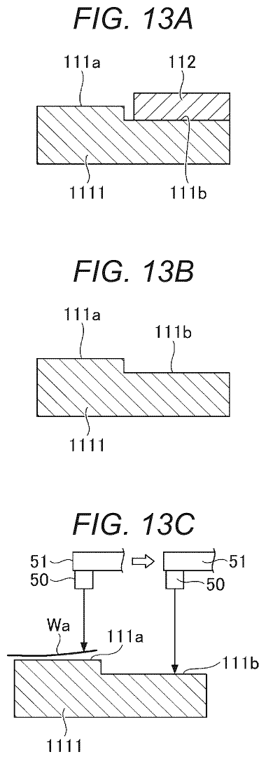

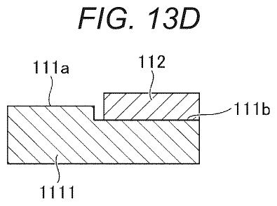

Next, the substrate processing (including the measurement processing) that includes edge ring transfer processing according to one embodiment will be described with reference to FIGS. 12 and 13A to 13D. FIG. 12 is a flowchart illustrating an example of transfer processing for the edge ring 112 according to the embodiment. FIGS. 13A to 13D are views illustrating the transfer of the edge ring 112 in FIG. 12.

When the processing is started, in step S10, the control device 2 determines whether the RF cumulative time exceeds the set time. When it is determined that the RF cumulative time does not exceed the set time, the control device 2 proceeds to step S11, executes the substrate processing (including the measurement processing) in FIG. 8 described above, and ends the present processing.

On the other hand, when it is determined that the calculated RF cumulative time exceeds the set time, the control device 2 proceeds to step S12 and automatically unloads the edge ring 112 by the edge ring transfer mechanism. The edge ring 112 is held in a suitably stockable container.

At this time, the edge ring 112 in FIG. 13A is lifted from the ring support surface (annular region 111b) by the pin (not illustrated), delivered to the edge ring transfer mechanism 53 (see FIG. 11B) inserted from the loading/unloading port 16, and unloaded. Accordingly, as illustrated in FIG. 13B, the ring support surface (annular region 111b) is exposed.

Next, in step S14, the control device 2 executes the substrate processing (including the measurement processing) in FIG. 8. In the second method for applying the reference surface, the ring support surface (annular region 111b) serves as the reference surface. That is, since the edge ring 112 is consumed, the surface of the edge ring 112 serves as the reference surface until the RF cumulative time exceeds the set time. After the RF cumulative time exceeds the set time, the ring support surface (annular region 111b) serves as the reference surface.

Accordingly, the ring support surface (annular region 111b) whose surface can maintain a predetermined height can be used as the reference surface during the measurement. In FIG. 13C, the processing in FIG. 8 is executed using the ring support surface (annular region 111b) as the reference surface instead of the surface of the edge ring 112, and the amount of change in the warpage amount of the substrate is calculated. Accordingly, even when the electrostatic chuck 1111 is consumed, the reference surface for measuring the adsorption force can be fixed. Accordingly, even when the edge ring 112 is consumed, the measurement accuracy of the measured value, using the sensor 50, of the warpage amount before and after the substrate is adsorbed can be maintained. Accordingly, it is possible to determine a decrease in the adsorption force based on the amount of change in the warpage amount.

When the processing in step S14 ends, in step S15, the control device 2 unloads the jig substrate Wa. Next, in step S17, the control device 2 loads the edge ring 112 unloaded in step S12 again by the edge ring transfer mechanism 53, disposes the edge ring 112 on the ring support surface (annular region 111b) (see FIG. 13D), and ends the processing.

According to the second method for applying the reference surface, the amount of consumption of the edge ring 112 is estimated based on the RF cumulative time, and when the RF cumulative time exceeds the set time, the ring support surface (annular region 111b) is used as the reference surface. That is, when measuring the warpage amount of the jig substrate Wa, measurement is performed with the ring support surface (annular region 111b) serving as the reference surface. Accordingly, the adsorption force of the substrate can still be quantitatively measured.

An example has been described in which the jig edge ring 112a is automatically transferred, and alternatively, the jig edge ring 112a may be manually transferred.

### Example of Effects

There is a method of supplying a heat transfer (He) gas between the rear surface of the substrate W and a surface of the electrostatic chuck 1111, measuring an amount of leakage thereof, and measuring the number of particles generated at the rear surface of the substrate, thereby indirectly checking the adsorption force when the substrate is electrostatically adsorbed.

However, in this case, it is not possible to directly check the adsorption force when the substrate is electrostatically adsorbed. In contrast, according to the substrate processing method of the embodiment, the amount of change in the warpage amount when the substrate is adsorbed to the electrostatic chuck 1111 is measured using the sensor 50 attached to the fork of the transfer arm 51. The amount of change in the warpage amount of the substrate indicates the adsorption force of the substrate. Thus, the adsorption force of the electrostatic chuck 1111 can be quantitatively measured accordingly. In addition, since the amount of change in the warpage amount is also proportional to an amount of consumption of the electrostatic chuck 1111, the amount of consumption of the electrostatic chuck 1111 can be determined based on the amount of change in the warpage amount.

When the amount of change in the warpage amount of the substrate falls below the threshold value, the adsorption force of the substrate can be increased by performing control to increase a direct current applied to the electrostatic electrode 1111b.

### Modification of Method for Applying Reference Surface

The measurement of the distance from the sensor 50 to the reference surface may be performed only before adsorption. For example, if the distance C1 from the sensor 50 to the reference surface (the surface of the edge ring 112) before the substrate is adsorbed illustrated in FIG. 6A is measured, the measurement of the distance C2 from the sensor 50 to the reference surface (the surface of the edge ring 112) after adsorption in FIG. 6B may be omitted. In this case, step S4-1 in FIG. 8 may be skipped, and the difference ΔL2 in step S4-3 may be calculated based on a difference between the distance D2 and the distance C1.

Each of a plurality of sensors 50 may measure the distance from the sensor 50 to the reference surface, or one of the sensors 50 may measure the distance from the sensor 50 to the reference surface. For example, the plurality of sensors 50 may measure a plurality of second distances (corresponding to the distance C1 in FIG. 6A) from the plurality of sensors 50 to the reference surface before adsorption when the transfer arm 51 moves around the substrate W (including the jig substrate Wa), and may measure a plurality of fourth distances (corresponding to the distance C2 in FIG. 6B) from the plurality of sensors 50 to the reference surface after adsorption. One sensor 50 among the plurality of sensors 50 may measure one second distance or a plurality of second distances from the sensor 50 to the reference surface before adsorption, and measure one fourth distance or a plurality of fourth distances from the sensor 50 to the reference surface after adsorption.

For example, the plurality of sensors 50 may measure a plurality of first distances (corresponding to the distance D1 in FIG. 6A) from the plurality of sensors 50 to the outer peripheral portion of the substrate W before adsorption when the transfer arm 51 moves on the outer peripheral portion of the substrate W (including the jig substrate Wa), and may measure a plurality of third distances (corresponding to the distance D2 in FIG. 6B) from the plurality of sensors 50 to the outer peripheral portion of the substrate W after adsorption. The control device 2 may calculate a plurality of first differences based on the plurality of first distances and the one second distance or the plurality of second distances, and may calculate a plurality of second differences based on the plurality of third distances and the one fourth distance or the plurality of fourth distances. The control device 2 may calculate the amount of change in the warpage amount of the substrate based on the plurality of first differences and the plurality of second differences.

When the edge ring 112 is new or the jig edge ring 112a is disposed, the distance C1 from the sensor 50 to the reference surface (the surface of the edge ring 112) may be measured in advance and stored as an initial value Cᵢₙᵢₜᵢₐₗ before adsorption illustrated in FIG. 6A. In this case, when the substrate processing (measurement processing) in FIG. 8 is executed, steps S2-1 and S4-1 may be skipped, and the initial value Cᵢₙᵢₜᵢₐₗ may be substituted for C1 and C2 in steps S2-3 and S4-3. Accordingly, transfer of the edge ring 112 and the jig edge ring 112a is not required. When the substrate processing (measurement processing) in FIG. 8 is executed, C1 measured in the first step S2-1 may be stored as the initial value Cᵢₙᵢₜᵢₐₗ.

However, the height of the reference surface (the surface of the edge ring 112) may vary depending on a measurement position in a circumferential direction or a radial direction of the edge ring 112. In addition, the height of the reference surface (the surface of the edge ring 112) may vary without being fixed due to consumption of the edge ring 112, the adsorption state of the substrate W, or the like. Therefore, it is preferable to measure the distance (height)

C1 of the reference surface before adsorption and the distance (height) C2 of the reference surface after adsorption each time in steps S2-1 and S4-1 in FIG. 8.

The reference surface before and after adsorption may be the substrate support surface (central region 111a), the ring support surface (annular region 111b), or a surface of the cover ring provided at an outer periphery of the edge ring 112.

The embodiments disclosed above include, for example, the following aspects.

### Appendix 1

A substrate processing apparatus including:
a chamber configured to process a substrate,
a substrate support disposed in the chamber and including an electrostatic chuck that includes an electrostatic electrode and a substrate support surface, the substrate support being configured to electrostatically adsorb the substrate to the substrate support surface by applying
a direct-current voltage to the electrostatic electrode,
a transfer arm configured to transfer the substrate into the chamber,
a sensor disposed at the transfer arm, the sensor being configured to measure a distance from the sensor to the substrate and a distance from the sensor to a reference surface set at the substrate support, and
a control device configured to
   acquire a first distance from the sensor to the substrate before adsorbing and a second distance from the sensor to the reference surface before adsorbing, which are measured by the sensor, and calculate a first difference that is a difference between the first distance and the second distance,
   acquire a third distance from the sensor to the substrate after adsorbing and a fourth distance from the sensor to the reference surface after adsorbing, which are measured by the sensor, and calculate a second difference that is a difference between the third distance and the fourth distance,
   calculate an amount of change in a warpage amount of the substrate based on the first difference and the second difference, and
   control the direct-current voltage to be applied to the electrostatic electrode based on the amount of change in the warpage amount of the substrate.

### Appendix 2

The substrate processing apparatus according to appendix 1, in which
the reference surface is a surface of an edge ring disposed around the substrate support surface.

### Appendix 3

The substrate processing apparatus according to appendix 1, in which
the reference surface is a ring support surface formed around the substrate support surface of the electrostatic chuck.

### Appendix 4

The substrate processing apparatus according to any one of appendices 1 to 3, in which
the first distance is a distance from the sensor to an outer peripheral portion of the substrate before the substrate is electrostatically adsorbed to the substrate support surface, and
the third distance is a distance from the sensor to the outer peripheral portion of the substrate after the substrate is electrostatically adsorbed to the substrate support surface.

### Appendix 5

The substrate processing apparatus according to any one of appendices 1 to 4, in which
a plurality of the sensors are disposed at the transfer arm,
the sensors measure a plurality of the first distances from the sensors to the substrate before the substrate is electrostatically adsorbed to the substrate support surface and measure a plurality of the third distances from the sensors to the substrate after the substrate is electrostatically adsorbed to the substrate support surface when the transfer arm moves on the substrate, and
the control device
   calculates a plurality of the first differences based on the first distances and the second distance,
   calculates a plurality of the second differences based on the third distances and the fourth distance, and
   calculates the amount of change in the warpage amount of the substrate based on the first differences and the second differences.

### Appendix 6

The substrate processing apparatus according to appendix 5, in which
the sensors measure a plurality of the second distances from the sensors to the reference surface before the substrate is electrostatically adsorbed to the substrate support surface and measure a plurality of the fourth distances from the sensors to the reference surface after the substrate is electrostatically adsorbed to the substrate support surface when the transfer arm moves around the substrate, and
the control device
   calculates a plurality of the first differences based on the first distances and the second distances,
   calculates a plurality of the second differences based on the third distances and the fourth distances, and
   calculates the amount of change in the warpage amount of the substrate based on the first differences and the second differences.

### Appendix 7

The substrate processing apparatus according to any one of appendices 1 to 6, in which
the control device determines an adsorption state of the substrate based on the calculated amount of change in the warpage amount of the substrate.

### Appendix 8

The substrate processing apparatus according to any one of appendices 1 to 6, further including:
an RF power source configured to supply RF power for generating plasma, in which the control device calculates an RF cumulative time during which the RF power is supplied from the RF power source into the chamber.

### Appendix 9

The substrate apparatus according to appendix 8, further including:
an edge ring transfer mechanism configured to automatically transfer an edge ring disposed around the substrate support surface, in which
when the RF cumulative time is determined to exceed a set time, the control device loads a jig edge ring and disposes the jig edge ring around the substrate support surface after the edge ring is unloaded by the edge ring transfer mechanism, and
the reference surface is a surface of the edge ring until the RF cumulative time exceeds the set time, and is a surface of the jig edge ring after the RF cumulative time exceeds the set time.

### Appendix 10

The substrate processing apparatus according to appendix 8 or 9, in which
the control device determines an adsorption state of the substrate based on the RF cumulative time and the amount of change in the warpage amount of the substrate.

### Appendix 11

The substrate processing apparatus according to any one of appendices 8 to 10, further including:
a DC power supply configured to control the direct-current voltage to be applied to the electrostatic electrode, in which
the control device controls the direct-current voltage applied from the DC power supply to the electrostatic electrode based on the RF cumulative time and the calculated amount of change in the warpage amount of the substrate by referring to a storage that stores correlation information on the amount of change in the warpage amount of the substrate, the RF cumulative time, and the direct-current voltage to be applied to the electrostatic electrode.

### Appendix 12

The substrate processing apparatus according to appendix 11, in which
the control device performs control to increase the direct-current voltage applied from the DC power supply to the electrostatic electrode when it is determined that the amount of change in the warpage amount of the substrate is smaller than a preset threshold value.

### Appendix 13

The substrate processing apparatus according to appendix 12, in which
after performing control to increase the direct-current voltage applied from the DC power supply to the electrostatic electrode, the control device determines that the substrate support is required to be replaced when it is determined that the calculated amount of change in the warpage amount of the substrate does not exceed the threshold value.

### Appendix 14

The substrate processing apparatus according to any one of appendices 1 to 13, in which
the sensor is a white light confocal displacement sensor.

### Appendix 15

A substrate processing method performed by
a chamber configured to process a substrate,
a substrate support disposed in the chamber and including an electrostatic chuck that includes an electrostatic electrode and a substrate support surface, the substrate support being configured to electrostatically adsorb the substrate to the substrate support surface by applying a direct-current voltage to the electrostatic electrode,
a transfer arm configured to transfer the substrate into the chamber, and
a sensor disposed at the transfer arm, the sensor being configured to measure a distance from the sensor to the substrate and a distance from the sensor to a reference surface set at the substrate support,
the method including:
acquiring a first distance from the sensor to the substrate before the substrate is electrostatically adsorbed to the substrate support surface and a second distance from the sensor to the reference surface before the substrate is electrostatically adsorbed to the substrate support surface, which are measured by the sensor,
calculating a first difference that is a difference between the first distance and the second distance,
acquiring a third distance from the sensor to the substrate after the substrate is electrostatically adsorbed to the substrate support surface and a fourth distance from the sensor to the reference surface after the substrate is electrostatically adsorbed to the substrate support surface, which are measured by the sensor,
calculating a second difference that is a difference between the third distance and the fourth distance,
calculating an amount of change in a warpage amount of the substrate based on the first difference and the second difference, and
controlling the direct-current voltage to be applied to the electrostatic electrode based on the amount of change in the warpage amount of the substrate.

The present invention is not limited to the configurations described in connection with the embodiments that have been described heretofore, or to the combinations of these configurations with other elements. Various variations and modifications may be made without departing from the scope of the present invention, and may be adopted according to applications. In addition, matters described in a plurality of embodiments may adopt other configurations within a non-contradictory scope, and may be combined within the non-contradictory scope.

For example, the above embodiment has been described by taking a capacitively-coupled plasma apparatus as an example, but the present disclosure is not limited thereto and may be applied to other plasma apparatuses. For example, an inductively coupled plasma (ICP) apparatus may be used instead of the capacitively-coupled plasma apparatus. In this case, the inductively coupled plasma apparatus includes an antenna and a lower electrode. The lower electrode is disposed in the substrate support, and the antenna is disposed on an upper portion of or above a chamber. An RF generator is coupled to the antenna, and a DC generator is coupled to the lower electrode. Therefore, the RF generator is coupled to an upper electrode of the capacitively-coupled plasma apparatus or the antenna of the inductively coupled plasma apparatus. That is, the RF generator is coupled to the plasma processing chamber 10.

This application claims the benefit of priority from Japanese Patent Application No. 2023-20206, filed on Feb. 13, 2023, which is hereby incorporated by reference in its entirety.

1. A substrate processing apparatus comprising:
a chamber configured to process a substrate,
a substrate support disposed in the chamber and including an electrostatic chuck, the electrostatic chuck including an electrostatic electrode and a substrate support surface, the substrate support being configured to electrostatically adsorb the substrate to the substrate support surface by applying a direct-current voltage to the electrostatic electrode,
a transfer arm configured to transfer the substrate into the chamber,
a sensor disposed in the transfer arm, the sensor being configured to:
measure a distance from the sensor to the substrate, and
measure a distance from the sensor to a reference surface set at the substrate support, and
processing circuitry configured to:
acquire a first distance from the sensor to the substrate before adsorbing and a second distance from the sensor to the reference surface before the adsorbing, the first distance and the second distance being measured by the sensor,
calculate a first difference that is a difference between the first distance and the second distance,
acquire a third distance from the sensor to the substrate after the adsorbing and a fourth distance from the sensor to the reference surface after the adsorbing, the third distance and the fourth distance being measured by the sensor,
calculate a second difference that is a difference between the third distance and the fourth distance,
calculate an amount of change in a warpage amount of the substrate based on the first difference and the second difference, and
control the direct-current voltage to be applied to the electrostatic electrode based on the amount of change in the warpage amount of the substrate.

2. The substrate processing apparatus according to claim 1, wherein
the reference surface is a surface of an edge ring disposed around the substrate support surface.

3. The substrate processing apparatus according to claim 1, wherein
the reference surface is a ring support surface formed around the substrate support surface of the electrostatic chuck.

4. The substrate processing apparatus according to claim 1, wherein
the first distance is a distance from the sensor to an outer peripheral portion of the substrate before the substrate is electrostatically adsorbed to the substrate support surface, and
the third distance is a distance from the sensor to the outer peripheral portion of the substrate after the substrate is electrostatically adsorbed to the substrate support surface.

5. The substrate processing apparatus according to claim 1, wherein
the sensor of the transfer arm is among a plurality of the sensors disposed in the transfer arm,
the plurality of sensors measure a plurality of the first distances from the plurality of sensors to the substrate before the substrate is electrostatically adsorbed to the substrate support surface and the plurality of sensors measure a plurality of the third distances from the sensors to the substrate after the substrate is electrostatically adsorbed to the substrate support surface when the transfer arm moves on the substrate, and
the processing circuitry
calculates a plurality of the first differences based on the first distances and the second distance,
calculates a plurality of the second differences based on the third distances and the fourth distance, and
calculates the amount of change in the warpage amount of the substrate based on the first differences and the second differences.

6. The substrate processing apparatus according to claim 5, wherein
the plurality of sensors measure a plurality of the second distances from the plurality of sensors to the reference surface before the substrate is electrostatically adsorbed to the substrate support surface and the plurality of sensors measure a plurality of the fourth distances from the sensors to the reference surface after the substrate is electrostatically adsorbed to the substrate support surface when the transfer arm moves around the substrate, and
the processing circuitry
calculates a plurality of the first differences based on the first distances and the second distances,
calculates a plurality of the second differences based on the third distances and the fourth distances, and
calculates the amount of change in the warpage amount of the substrate based on the first differences and the second differences.

7. The substrate processing apparatus according to claim 1, wherein
the processing circuitry determines an adsorption state of the substrate based on the calculated amount of change in the warpage amount of the substrate.

8. The substrate processing apparatus according to claim 1, further comprising:
an RF power source configured to supply RF power for generating plasma, wherein
the processing circuitry calculates an RF cumulative time during which the RF power is supplied from the RF power source into the chamber.

9. The substrate processing apparatus according to claim 8, further comprising:
an edge ring transferrer configured to automatically transfer an edge ring disposed around the substrate support surface, wherein
when the RF cumulative time is determined to exceed a set time, the processing circuitry controls the edge ring transferrer to load a jig edge ring and dispose the jig edge ring around the substrate support surface after the edge ring is unloaded by the edge ring transfer mechanism, and
the reference surface is a surface of the edge ring until the RF cumulative time exceeds the set time, and is a surface of the jig edge ring after the RF cumulative time exceeds the set time.

10. The substrate processing apparatus according to claim 8, wherein
the processing circuitry determines an adsorption state of the substrate based on the RF cumulative time and the amount of change in the warpage amount of the substrate.

11. The substrate processing apparatus according to claim 8, further comprising:
a DC power supply configured to control the direct-current voltage to be applied to the electrostatic electrode, wherein
the processing circuitry controls the direct-current voltage applied from the DC power supply to the electrostatic electrode based on the RF cumulative time and the calculated amount of change in the warpage amount of the substrate by referring to a storage that stores correlation information on the amount of change in the warpage amount of the substrate, the RF cumulative time, and the direct-current voltage to be applied to the electrostatic electrode.

12. The substrate processing apparatus according to claim 11, wherein
the processing circuitry performs control to increase the direct-current voltage applied from the DC power supply to the electrostatic electrode in response to determining that the amount of change in the warpage amount of the substrate is smaller than a preset threshold value.

13. The substrate processing apparatus according to claim 12, wherein
after performing control to increase the direct-current voltage applied from the DC power supply to the electrostatic electrode, the processing circuitry determines that the substrate support is required to be replaced when it is determined that the calculated amount of change in the warpage amount of the substrate does not exceed the threshold value.

14. The substrate processing apparatus according to claim 1, wherein
the sensor is a white light confocal displacement sensor.

15. A substrate processing method, comprising:
acquiring a first distance from a sensor to the substrate before the substrate is electrostatically adsorbed to a substrate support surface and a second distance from the sensor to a reference surface before the substrate is electrostatically adsorbed to the substrate support surface, the reference surface being set at the substrate support,
wherein the sensor is disposed on a transfer arm;
calculating a first difference that is a difference between the first distance and the second distance,
acquiring a third distance from the sensor to the substrate after the substrate is electrostatically adsorbed to the substrate support surface and a fourth distance from the sensor to the reference surface after the substrate is electrostatically adsorbed to the substrate support surface, which are measured by the sensor,
calculating a second difference that is a difference between the third distance and the fourth distance,
calculating an amount of change in a warpage amount of the substrate based on the first difference and the second difference, and
controlling a direct-current voltage applied to an electrostatic electrode based on the amount of change in the warpage amount of the substrate,
wherein the substrate support is disposed in a chamber and includes an electrostatic chuck, and
the electrostatic chuck includes the electrostatic electrode and the substrate support surface.

16. The substrate processing apparatus according to claim 5, wherein the plurality of sensors are disposed at distal ends of a bifurcated fork of the transfer arm, each sensor being positioned on a lower surface of a respective distal end to measure distances to the substrate and the reference surface without interfering with substrate holding.

17. The substrate processing apparatus according to claim 1, wherein the substrate is a jig substrate configured as a reference substrate for measuring the amount of change in the warpage amount, the jig substrate having a predetermined warpage amount before adsorption.

18. The substrate processing apparatus according to claim 1, wherein the reference surface is a surface of a cover ring disposed at an outer periphery of an edge ring around the substrate support surface.

19. The substrate processing apparatus according to claim 5, wherein the processing circuitry is configured to generate a distribution of the first differences and the second differences across a plurality of measurement points along a direction crossing a boundary between the reference surface and the substrate, and calculate the amount of change in the warpage amount based on the distribution.

20. The substrate processing method according to claim 15, further comprising:
determining the direct-current voltage to be applied to the electrostatic electrode when the amount of change in the warpage amount is smaller than a preset threshold value, wherein the determining includes referring to a correlation graph stored in a storage, the correlation graph representing relationships among the amount of change in the warpage amount, an RF cumulative time, and the direct-current voltage.
